(19) United States
(12) Patent Application Publication
(10) Pub. No.: US 2016/0300731 A1
(43) Pub. Date: Oct. 13, 2016

(54) METHODS OF ETCHBACK PROFILE TUNING

(71) Applicant: APPLIED MATERIALS, INC., Santa Clara, CA (US)

(72) Inventors: KAI WU, Palo Alto, CA (US); VIKASH BANTHIA, Los Altos, CA (US)

(21) Appl. No.: 15/091,951

(22) Filed: Apr. 6, 2016

Related U.S. Application Data
(60) Provisional application No. 62/146,000, filed on Apr. 10, 2015.

(51) Int. Cl. H01L 21/3213; H01L 21/3205; H01L 21/768

(52) U.S. Cl. CPC H01L 21/32136; H01L 21/76847; H01L 21/32051

(57) ABSTRACT

A method of controlling an etch profile includes introducing a tungsten containing gas into a processing chamber; depositing a first tungsten film lining sidewalls of a feature formed in a substrate using the tungsten containing gas in the processing chamber; and treating the first tungsten film in the processing chamber using the tungsten containing gas until a particular etch profile is attained by repeatedly alternating between etching the first tungsten film for a first interval and stopping the etching of the first tungsten film for a second interval by at least one of purging the tungsten containing gas from the process chamber or turning off a power supply that powers the etching of the first tungsten film.

### CROSS-REFERENCE TO RELATED APPLICATIONS

This application claims benefit of U.S. provisional patent application Ser. No. 62/146,000, filed Apr. 10, 2015, which is herein incorporated by reference in its entirety.

### FIELD

Embodiments of the present disclosure generally relate to the processing of substrates and, more particularly, to methods of controlling an etch profile of features formed in substrates.

### BACKGROUND

The shrinking dimensions of the features of the circuits and devices used in integrated circuits have placed additional demands on processes for manufacturing the integrated circuits. For example, forming multilevel interconnects used in integrated circuit technology may include precise processing of high aspect ratio features, such as vias and other interconnects. Reliable formation of these interconnects may be used to increase circuit density and quality of individual substrates.

Metallization of features formed on substrates includes deposition of metals such as tungsten. Tungsten may be used for metal fill of source contacts, drain contacts, metal gate fill, and gate contacts as well as in other applications. With technology node shrinkage, tungsten films may be used to obtain low resistivity and low roughness of devices and for integration with subsequent process steps. Chemical vapor deposition (CVD) may be a process technology used for a metal fill of tungsten. A pattern may be etched in an underlying interlayer dielectric (ILD) material, and the tungsten may then be deposited to fill the etched material.

However, the reduction in feature sizes has often increased difficulty in the metal fill process. For example, when a dielectric material layer is formed on the sidewalls and bottom surface of a feature, the deposition process may deposit a greater thickness of dielectric material on a part of the sidewalls that is nearer to an opening of the feature. Then, the subsequent CVD formation of the tungsten on the side walls may close off the feature at the feature opening before the lower portion of the feature has completely filled resulting in a void forming within the feature. The presence of the void may change the material and operating characteristics of the interconnect feature and may eventually cause improper operation and premature breakdown of the device. For example, to be efficient, a conductive element or line may need to carry an almost practical maximum current density to achieve the same current flow density or higher in smaller features in future devices.

Therefore, the inventors have provided a process to control the profile of the sidewalls of high aspect ratio features so that subsequent void-free (or substantially void-free) filling of the high aspect ratio with a metal may be attained.

### SUMMARY

Methods of controlling an etch profile are provided herein. In some embodiments, a method of controlling an etch profile includes; introducing a tungsten containing gas into a processing chamber; depositing a first tungsten film lining sidewalls of a feature formed in a substrate using the tungsten containing gas in the processing chamber; and treating the first tungsten film in the processing chamber using the tungsten containing gas until a particular etch profile is attained by repeatedly alternating between etching the first tungsten film for a first interval and stopping the etching of the first tungsten film for a second interval by at least one of purging the tungsten containing gas from the process chamber or turning off a power supply that powers the etching of the first tungsten film.

In some embodiments, a method of controlling an etch profile includes forming an adhesion layer along sidewalls of a feature formed in a substrate, wherein sidewalls of the feature slant towards each other at an upper part of the feature; introducing a tungsten containing gas into a processing chamber having the substrate disposed therein; forming a first tungsten film atop the adhesion layer in the processing chamber; treating the first tungsten film in the processing chamber using the tungsten containing gas until a particular etch profile is attained by repeatedly alternating between plasma etching the first tungsten film for a first interval of about 1 sec to about 5 sec and stopping the etching of the first tungsten film for a second interval of about 1 sec to about 10 sec by at least one of purging the tungsten containing gas from the process chamber or turning off RF power that generates the plasma; and forming a second tungsten film atop the first tungsten film after treating the first tungsten film.

In some embodiments, non-transitory computer readable medium having instructions stored thereon that, when executed, cause a method of controlling an etch profile that includes; introducing a tungsten containing gas into a processing chamber; depositing a first tungsten film lining sidewalls of a feature formed in a substrate using the tungsten containing gas in the processing chamber; and treating the first tungsten film in the processing chamber using the tungsten containing gas until a particular etch profile is attained by repeatedly alternating between etching the first tungsten film for a first interval and stopping the etching of the first tungsten film for a second interval by at least one of purging the tungsten containing gas from the process chamber or turning off a power supply that powers the etching of the first tungsten film.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, that the appended drawings illustrate only typical embodiments of the disclosure and are therefore not to be considered limiting of scope, for the disclosure may admit to other equally effective embodiments.

FIG. 1 is a diagram showing of an example of a method of controlling an etch profile in accordance with some embodiments of the present disclosure.

FIGS. 2A-2F are schematic cross-sectional views of a substrate with a feature formed in the substrate in which a method of controlling an etch profile may be carried out in accordance with some embodiments of the present disclosure

FIG. 3 depicts an example of a process chamber suitable for performing a method of controlling an etch profile in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure advantageously provide for treating a first tungsten film by repeatedly alternating between etching the first tungsten film for a first interval and stopping the etching the first tungsten film for a second interval until a particular etch profile for the sidewalls of the material may be attained. Advantageously, by repeatedly alternating between etching the first tungsten film for the first interval and stopping the etching the first tungsten film for the second interval, an overhang portion of the first tungsten film may be removed. Advantageously, by removing the overhang portion of the first tungsten film and attaining a predetermined profile for the sidewalls of the first tungsten film, the formation of a void within a feature may be avoided. Advantageously, deposition of a second tungsten film may fill a lower portion of a feature starting from a bottom surface of the feature until an opening in the feature may be completely filled.

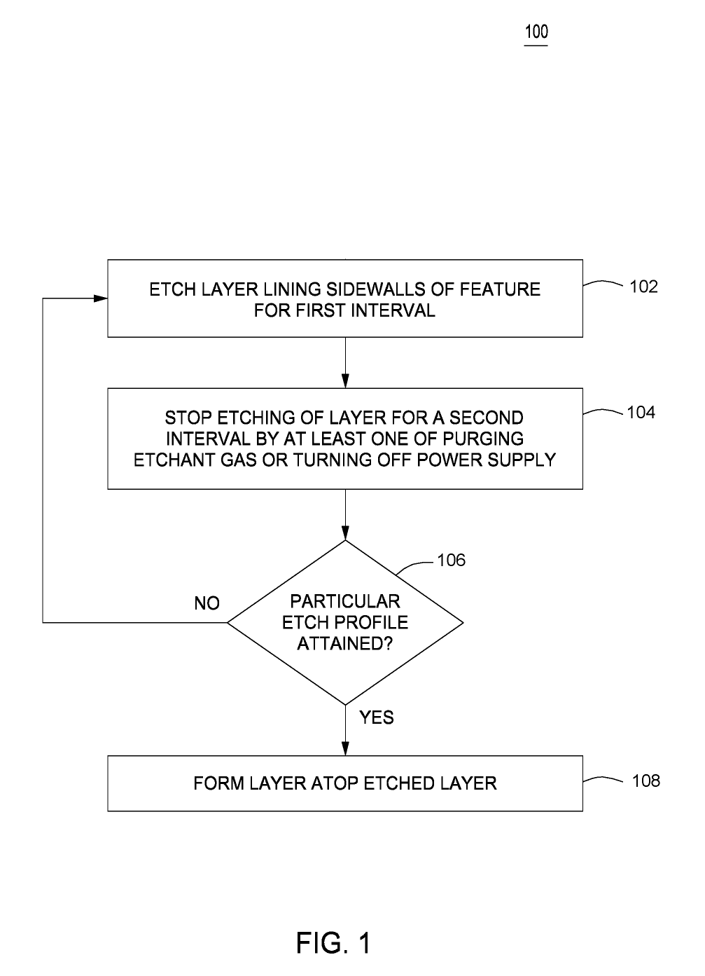

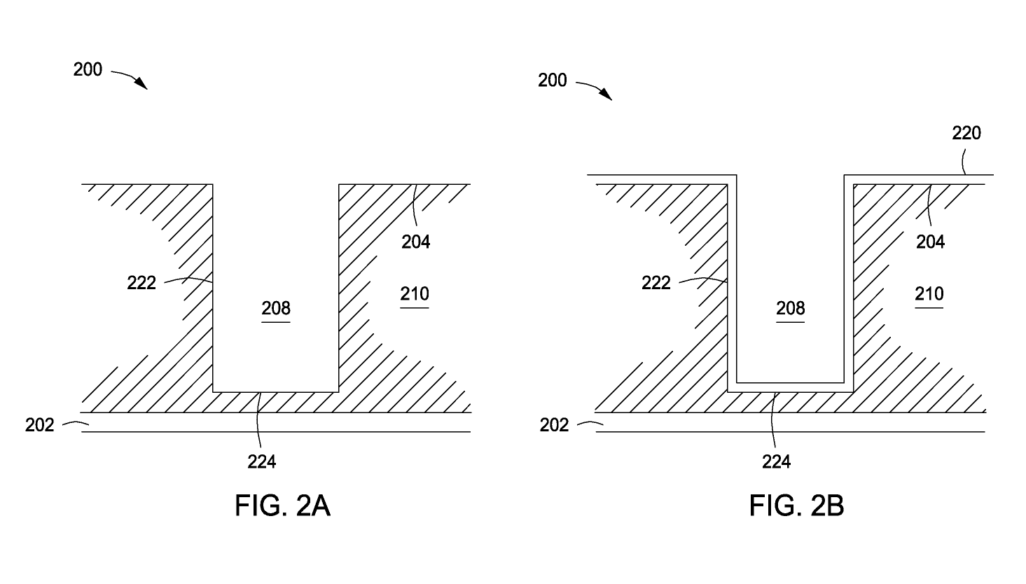

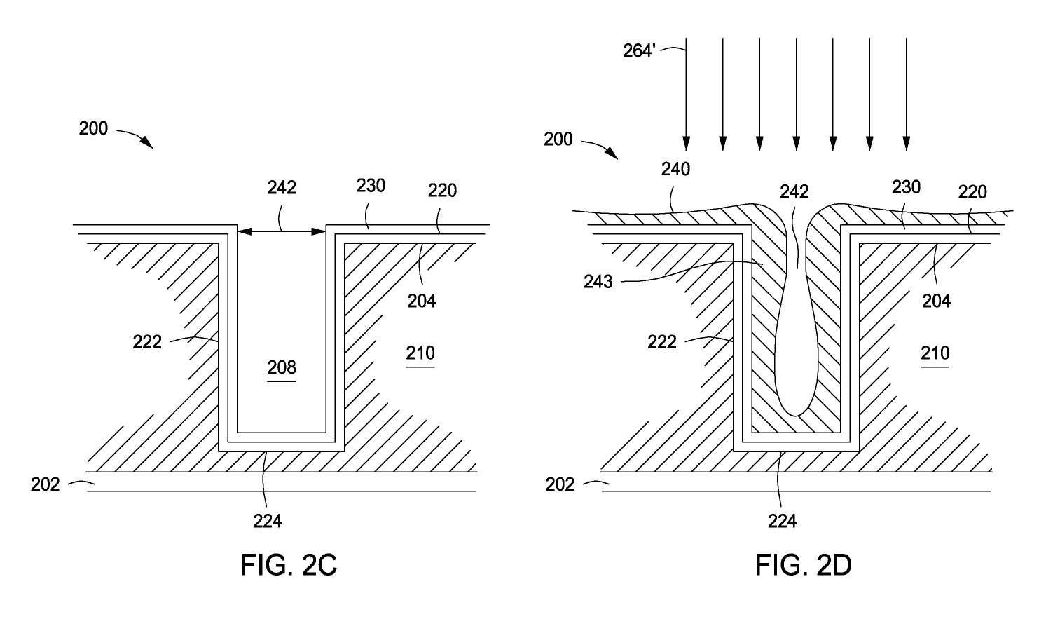

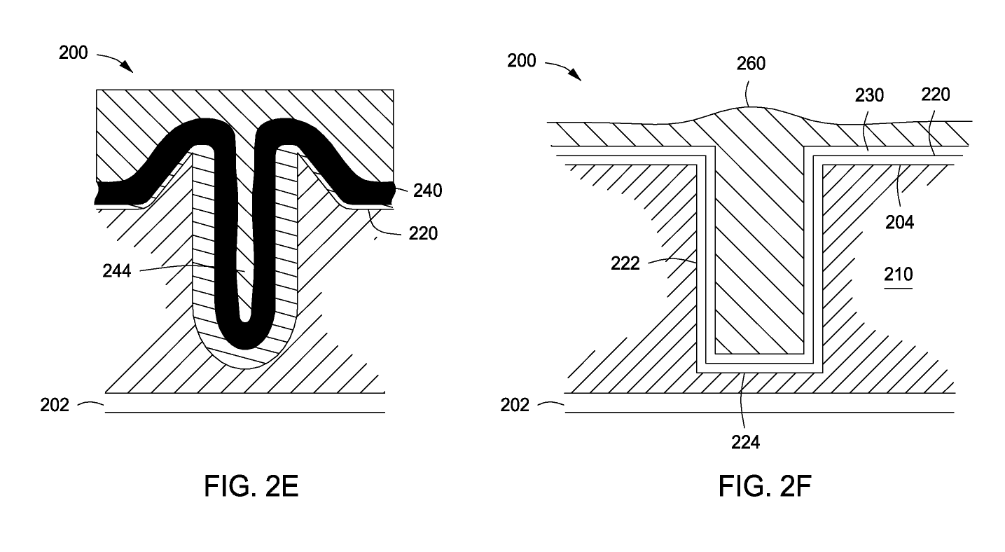

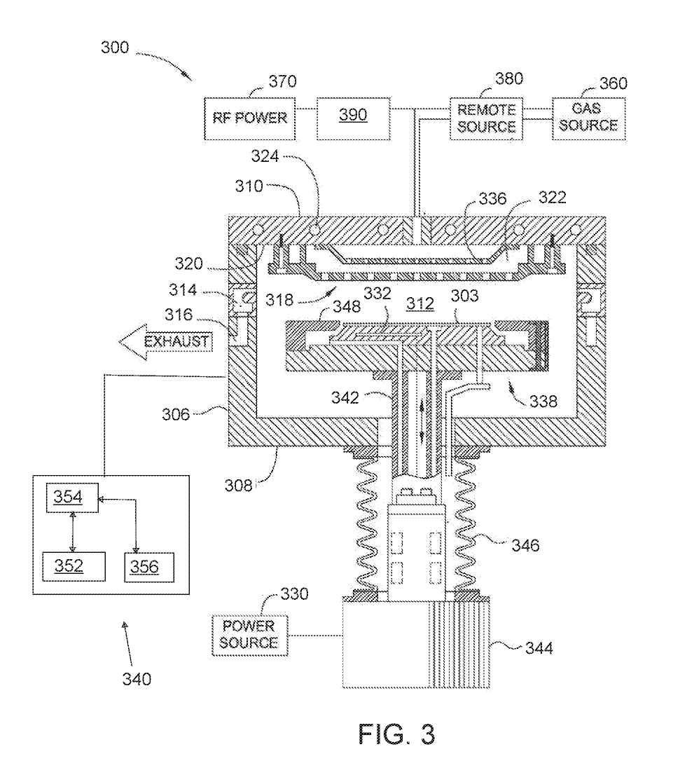

FIG. 1 illustrates an example of a method 100 of controlling an etch profile on a substrate in accordance with some embodiments of the present disclosure. In some embodiments, the method 100 may be carried out on a substrate 200 with a feature 208 formed in the substrate as shown in FIGS. 2A-2F and described below. In some embodiments, the method may be carried out using the process chamber of FIG. 3, which is described below.

The method 100 is performed on a substrate having a feature formed in the substrate and a first tungsten film lining the sidewalls and bottom of the feature are provided in a processing chamber, such as using the process as shown in FIGS. 2A-2D.

For example, FIG. 2A depicts substrate 200 that contains a dielectric layer 210 disposed on a substrate 202 and a feature 208 formed or otherwise contained within the dielectric layer 210. The feature 208 has one or more sidewalls 222 and a bottom surface 224. In some embodiments, features such as vias, trenches, lines, contact holes, or other features utilized in a semiconductor, solar, or other electronic devices, such as high aspect ratio contact plugs. In some embodiments, where the feature is a via, the via may have a high depth to width aspect ratio of, e.g., about 20-50. In some embodiments, substrate 202 is a silicon substrate or at least contains silicon or a silicon-based material. In some embodiments, the substrate 200 is a semiconductor substrate having a silicon substrate or wafer as the substrate 202, and the dielectric layer 210 contains at least one dielectric material, such as silicon, monocrystalline silicon, microcrystalline silicon, polycrystalline silicon (polysilicon), amorphous silicon, hydrogenated amorphous silicon, silicon oxide materials, dopant derivatives thereof, or combinations thereof.

In some embodiments, an adhesion layer may be formed on the dielectric layer disposed on the substrate, as depicted in FIG. 2B. The adhesion layer 220 forms a relatively uniform layer of material on the planar upper surface 204 of the dielectric layer 210, the sidewalls 222 of the feature 208, and the bottom surface 224 of the feature 208. In some embodiments, the adhesion layer 220 contains a metal or a metal nitride material, such as titanium, titanium nitride, alloys thereof, or combinations thereof. In some embodiments, the adhesion layer 220 may include tantalum (Ta), tungsten nitride (WN), titanium nitride (TiN), TiNₓSi_{y}, tantalum nitride (TaNₓ), silicon nitride (SiN), tungsten (W), CoWP, NiMoP, NiMoB, ruthenium (Ru), RuO₂, molybdenum (Mo), MoₓN_{y}, where x and y are non-zero numbers, and combinations thereof. Adhesion layer 220 may have a thickness within a range from about 2 Å to about 100 Å, more narrowly within a range from about 3 Å to about 80 Å, more narrowly within a range from about 2 Å to about 50 Å, more narrowly within a range from about 5 Å to about 25 Å, more narrowly within a range from about 5 Å to about 20 Å, more narrowly within a range from about 5 Å to about 15 Å, and more narrowly within a range from about 5 Å to about 10 Å. Adhesion layer 220 is generally deposited by chemical vapor deposition (CVD), atomic layer deposition (ALD) or physical vapor deposition (PVD) processes.

In some embodiments, a nucleation layer 230 of predetermined thickness is deposited on adhesion layer 220, as depicted in FIG. 2C. The nucleation layer 230 may be a thin layer of tungsten which acts as a growth site for subsequent film. In some embodiments, the nucleation layer 230 may be deposited by techniques such as atomic layer deposition (ALD), conventional chemical vapor deposition (CVD), or pulsed chemical vapor deposition (CVD). The nucleation layer deposition process may be performed in any suitable process chamber for performing the aforementioned ALD or CVD processes. In some embodiments, the nucleation layer may be deposited in the same process chamber used to deposit the adhesion layer. The nucleation layer 230 may comprise tungsten, tungsten alloys, tungsten-containing materials, e.g., tungsten boride or tungsten silicide, and combinations thereof. The nucleation layer 230 may be deposited to a thickness in a range of about 10 angstroms to about 200 angstroms, or about 50 angstroms to about 150 angstroms. The nucleation layer may be deposited by flowing a tungsten containing gas, e.g., a tungsten halide compound such as WF₆, and a hydrogen containing gas, e.g., H₂, B₂H₆, or SiH₄, into a processing chamber having the substrate disposed in the processing chamber.

In some embodiments, a first layer, such as a first tungsten film 240 of a bulk tungsten layer 260, is deposited on or over the nucleation layer 230, as depicted in FIG. 2D. The first tungsten film 240 is generally formed by thermal CVD, pulsed-CVD, plasma enhanced CVD (PE-CVD), or pulsed PE-CVD. The deposition process may be performed in any suitable process chamber for performing the aforementioned CVD processes. The first tungsten film 240 may contain metallic tungsten, tungsten alloys, tungsten-containing materials, tungsten boride, tungsten silicide, tungsten phosphide, or combinations thereof.

In some embodiments, the first tungsten film 240 may be deposited on or over nucleation layer 230 on substrate 200 which is simultaneously exposed to a tungsten containing gas, e.g., tungsten hexafluoride (WF₆), and a hydrogen containing gas, e.g., hydrogen (H₂), during a CVD process.

In some embodiments, the first tungsten film 240 may be deposited using the same processing gases, tungsten containing gas and hydrogen containing gases as were used to deposit the nucleation layer 230. In some embodiments, the first tungsten film 240 may be formed in the same process chamber as the nucleation layer 230.

In some embodiments, following deposition of the nucleation layer 230 and any subsequent purging or post soak processes, the substrate may be positioned on a substrate support pedestal having a temperature in the range of about 100° C. to about 600° C., or in some embodiments, in the range of about 100° C. to 230° C., or in some embodiments, in the range of about 200° C. to 230° C. In some embodiments, the temperature may be about 200° C. Deposition of the first tungsten film 240 may be performed with the process chamber at a pressure in the range of about 10 Torr to about 300 Torr, for example, in the range of about 30 Torr to about 100 Torr. In some embodiments, the pressure may be about 90 Torr. The reducing gas can be introduced with a carrier gas, such as argon (Ar), at a flow rate in the range of about 0 sccm to about 20,000 sccm. In some embodiments, argon may be introduced at a total flow rate of 11,000 sccm. A second flow of argon may be flowed through a purge guide (not shown in FIG. 3) at a rate from about 0 sccm to 2,000 sccm to prevent deposition gases from contacting the edge and backside of the substrate. In some embodiments, the argon edge purge flow may be 500 sccm. Similarly, a second flow of hydrogen gas (H₂) may be flowed through a purge guide (not shown in FIG. 3) at a rate from about 0 sccm to 6,000 sccm. In some embodiments, the hydrogen gas edge purge flow may be 2,500 sccm. In some embodiments, an additional flow of carrier gas, such as argon, may be introduced as a bottom purge in order to prevent deposition on the backside of the chamber heating elements. In some embodiments, the argon bottom purge flow may be 5,000 sccm. The tungsten-containing compound may be tungsten hexafluoride (WF₆) and may be introduced at a continuous flow rate in the range of about 50 sccm to 500 sccm, such as in the range of about 300 sccm to 200 sccm.

As depicted in FIG. 2D, the growth of the first tungsten film 240 along the sidewalls 222 of the feature 208 tends to form an overhang portion 243 of the first tungsten film 240. The presence of the overhang portion 243 would cause any further deposition of tungsten material to close off the opening 242 of the feature before the lower portion of the feature 208 has completely grown from the bottom surface 224 of the feature 208, resulting in a void forming within the feature 208.

Advantageously, the inventors have determined that treating the first tungsten film 240 by repeatedly alternating between etching the first tungsten film 240 for a first interval and stopping the etching the first tungsten film 240 for a second interval may remove the overhang portion 243 of the first tungsten film 240. Advantageously, the inventors have also determined that treating the first tungsten film 240 by repeatedly alternating between etching the first tungsten film 240 for a first interval and stopping the etching the first tungsten film 240 for a second interval, a particular advantageous etch profile for the sidewalls of the first tungsten film 240 may be attained. Advantageously, by removing the overhang portion 243 of the first tungsten film 240 and attaining a predetermined profile for the sidewalls of the first tungsten film, the formation of a void within the feature 208 may be avoided. Advantageously, further deposition of tungsten material may fill the lower portion of the feature 208 starting from the bottom surface 224 of the feature 208 until the opening 242 may be completely filled.

At 102, the first tungsten film 240 of the bulk tungsten layer 260 is etched for a first interval. In some embodiments, the first interval is about 1 sec to about 5 sec. In some embodiments, shown in FIG. 2D, the arrows 264′ represent the direction of the reactants formed of an etchant gas or gases during the etch process which causes the reactants to collide with the top (planar) surface of the first tungsten film 240.

In some embodiments, the first tungsten film 240 of the bulk tungsten layer 260 is etched using the tungsten containing gas to remove a portion of the overhang portion 243 of the first tungsten film 240. The etching process, also referred to as an etchback process, removes a portion of the first tungsten film 240 from along the sidewalls 222 of the feature 208. The etching process may also be performed in the same processing chamber as the tungsten deposition process. The etching process is generally performed using the same tungsten containing gases, e.g., tungsten hexafluoride (WF₆).

In some embodiments, the first tungsten film 240 is etched using a plasma etching process. The plasma may be formed by coupling RF power to a treatment gas such as helium (He), argon (Ar), oxygen (O₂), nitrogen (N₂), or combinations thereof. The plasma may be formed in the process chamber or by a remote plasma source (RPS) and delivered to the process chamber. In some embodiments, the tungsten containing gas is provided with the treatment gas. In some embodiments, the tungsten containing gas is provided to the process chamber separately from the treatment gas.

During the etch process, the pedestal (and, therefore, the substrate) may have a temperature in the range of about 100° C. to about 600° C., for example, in the range of about 300° C. to 230° C. In some embodiments, the temperature may be about 200° C. Etching of the first tungsten film 240 may be performed with the process chamber at a chamber pressure in the range of about 0.1 Torr to about 5 Torr, for example, in the range of about 0.5 Torr to about 2 Torr. In some embodiments, the pressure may be about 1 Torr. The treatment gas, e.g., argon (Ar), may be introduced at a flow rate in the range of about 100 sccm to about 3,000 sccm. In some embodiments, argon may be introduced at a total flow rate of 2,000 sccm. A second flow of argon may be flowed through a purge guide (not shown) at a rate from about 0 sccm to 2,000 sccm to prevent deposition gases from contacting the edge and backside of the substrate. In some embodiments, the argon edge purge flow may be 500 sccm. Similarly, a second flow of hydrogen gas (H₂) may be flowed through a purge guide (not shown in FIG. 3) at a rate from about 0 sccm to 6,000 sccm. In some embodiments, the hydrogen gas edge purge flow may be 2,500 sccm. In some embodiments, an additional flow of treatment gas, such as argon, may be introduced as a bottom purge in order to prevent deposition on the backside of the chamber heating elements. In some embodiments, the argon bottom purge flow may be 5,000 sccm. The tungsten-containing gas may be tungsten hexafluoride (WF₆) and may be introduced at a continuous flow rate in the range of about 1 sccm to 150 sccm, such as in the range of about 3 sccm to 100 sccm. The arrows 264′ may represent the direction of atomic fluorine during the etch process which may cause the atomic fluorine to collide with the top (planar) surface of the first tungsten film 240.

In some embodiments, where the plasma is formed by coupling RF power to the treatment gas, an RF power between about 50 watts (W) and about 100 W, such as about 75 W at an RF power frequency from about 10 MHz to about 30 MHZ. In some embodiments, about 13.56 MHz, may be used.

In some embodiments, where the plasma is formed in a remote plasma source (RPS) the power application may be from about 1,000 W to about 6,000 W, In some embodiments, from about 1,000 W to about 2,000 W, with a treatment gas flow rate, e.g., argon, from about 500 sccm to about 6,000 sccm.

Portions of the first tungsten film 240 may be removed at an etch rate from about 0.1 Å/second to about 10 Å/second. In some embodiments, the first tungsten film 240 may be removed at an etch rate from about 0.5 Å/second to about 3 Å/second.

At 104, the etching of the first tungsten film 240 is stopped for a second interval. In some embodiments, the second interval is about 1 sec to about 10 sec. The etching of the first tungsten film 240 may be stopped by purging an etchant gas from the processing chamber, by turning off a power supply that powers the etching of the first tungsten film 240, or by both purging an etchant gas from the process chamber and turning off the power supply. In some embodiments, an inert gas may be introduced into the process chamber prior to purging the etchant gas from the processing chamber. The inert gas may be at least one of helium or argon. In some embodiments, the inert gas may be introduced in the manner described above.

In some embodiments, the etching the first tungsten film 240 may be a plasma process, and turning off the power supply that powers the etching of the first tungsten film 240 may include removing RF power from the power supply that generates the plasma.

At 106, the first tungsten film is treated until a particular etch profile is attained. In some embodiments, 102 and 104 are repeated (e.g., etching and stopping the etch process are repeated). In some embodiments, as depicted in FIG. 2E, the particular etch profile is slanted sidewalls 244 of the first tungsten film 240. The slanted sidewalls 244 may slant outwardly such that the sidewalls 244 are nearer to each other proximate the bottom of the feature and further from each other proximate the opening of the feature.

Next, at 108, a second layer, such as second tungsten film of the bulk tungsten layer 260, is deposited over the first layer, such as the remaining portion of the first tungsten film 240, as depicted in FIG. 2F. The second tungsten film of the bulk tungsten layer 260 may be deposited in the same process chamber as the processes described above. The second tungsten film of the bulk tungsten layer 260 may be deposited using the same tungsten containing gases as used above.

The deposition of the second tungsten film of the bulk tungsten layer 260 may be performed on a pedestal having a temperature in the range of about 100° C. to about 600° C., for example, in the range of about 300° C. to about 230° C. In some embodiments, the temperature may be about 200° C. Deposition of the second tungsten film of the bulk tungsten layer 260 may be performed with the process chamber at a pressure in the range of about 10 Torr to about 300 Torr, or in some embodiments, in the range of about 30 Torr to about 100 Torr. In some embodiments, the pressure may be about 90 Torr. The reducing gas, for example, hydrogen gas (H₂), may be introduced at a continuous flow rate between 1,000 sccm and about 8,000 sccm, such as 5,000 sccm. The reducing gas can be introduced with a carrier gas, such as argon (Ar), at a flow rate in the range of about 0 sccm to about 20,000 sccm. In some embodiments, argon may be introduced at a total flow rate of 11,000 sccm. A second flow of argon may be flowed through a purge guide (not shown in FIG. 3) at a rate from about 0 sccm to 2,000 sccm to prevent deposition gases from contacting the edge and backside of the substrate. In some embodiments, the argon edge purge flow may be 500 sccm. Similarly, a second flow of hydrogen gas (H₂) may be flowed through a purge guide (not shown in FIG. 3) at a rate from about 0 sccm to 6,000 sccm. In some embodiments, the hydrogen gas edge purge flow may be 2,500 sccm. In some embodiments, an additional flow of carrier gas, such as argon, may be introduced as a bottom purge in order to prevent deposition on the backside of the chamber heating elements. In some embodiments, the argon bottom purge flow may be 5,000 sccm. The tungsten-containing compound may be tungsten hexafluoride (WF₆) and may be introduced at a continuous flow rate in the range of about 50 sccm to 500 sccm, such as in the range of about 300 sccm to 200 sccm.

If the predetermined thickness of bulk tungsten layer 260 has been achieved, the method 100 ends. If the predetermined thickness of the bulk tungsten layer 260 has not been achieved any of the aforementioned deposition and etching processes may be performed again. In some embodiments, the determination of the thickness of the of the tungsten bulk layer may be performed using conventional processes such as spectroscopic measurements.

FIG. 3 depicts a schematic diagram of a process chamber 300 of the kind that may be used to practice embodiments of the disclosure as discussed herein. The particular configuration of the process chamber 300 is illustrative and not limiting of the scope of the present disclosure. The process chamber 300 may be utilized alone or, more typically, as a processing module of an integrated semiconductor substrate processing system, or cluster tool, such as a ENDURA®, CENTURA®, or PRODUCER® integrated semiconductor substrate processing system, available from Applied Materials, Inc. of Santa Clara, Calif. In some embodiments, the process chamber 300 may be a deposition chamber, such as a chemical vapor deposition (CVD) chamber suitable for depositing materials, such as tungsten, on a substrate. Suitable deposition processing chambers include, but are not limited to, certain single wafer chambers on the ENDURA® platform and twin wafer chambers on the PRODUCER® platform, also available from Applied Materials, Inc. Methods of processing substrates in accordance with the present disclosure can be utilized on other chambers and platforms as well.

The processing chamber 300 may be part of a processing system that includes multiple processing chambers connected to a central transfer chamber and serviced by a robot (see FIG. 5). The processing chamber 300 includes walls 306, a bottom 308, and a lid 310 that define a processing volume 312. The walls 306 and bottom 308 are typically fabricated from a unitary block of aluminum. The walls 306 may have conduits (not shown) within through which a fluid may be passed to control the temperature of the walls 306. The processing chamber 300 may also include a pumping ring 314 that couples the processing volume 312 to an exhaust port 316 as well as other pumping components (not shown).

A substrate support assembly 338, which may be heated, may be centrally disposed within the processing chamber 300. The substrate support assembly 338 supports a substrate 303 during a deposition process. The substrate support assembly 338 generally is fabricated from aluminum, ceramic or a combination of aluminum and ceramic and typically includes a vacuum port (not shown) and at least one or more heating elements 332.

The vacuum port may be used to apply a vacuum between the substrate 303 and the substrate support assembly 338 to secure the substrate 303 to the substrate support assembly 338 during the deposition process. The one or more heating elements 332 may be, for example, electrodes disposed in the substrate support assembly 338, and coupled to a power source 330, to heat the substrate support assembly 338 and substrate 303 positioned on to a predetermined temperature.

Generally, the substrate support assembly 338 is coupled to a stem 342. The stem 342 provides a conduit for electrical leads, vacuum and gas supply lines between the substrate support assembly 338 and other components of the processing chamber 300. Additionally, the stem 342 couples the substrate support assembly 338 to a lift system 344 that moves the substrate support assembly 338 between an elevated position (as shown in FIG. 3) and a lowered position (not shown). Bellows 346 provides a vacuum seal between the processing volume 312 and the atmosphere outside the process chamber 300 while facilitating the movement of the substrate support assembly 338.

The substrate support assembly 338 additionally supports a circumscribing shadow ring 348. The shadow ring 348 is annular in form and typically comprises a ceramic material such as, for example, aluminum nitride. Generally, the shadow ring 348 prevents deposition at the edge of the substrate 303 and substrate support assembly 338.

The lid 310 is supported by the walls 306 and may be removable to allow for servicing of the processing chamber 300. The lid 310 may generally be comprised of aluminum and may additionally have heat transfer fluid channels 324 formed within. The heat transfer fluid channels 324 are coupled to a fluid source (not shown) that flows a heat transfer fluid through the lid 310. Fluid flowing through the heat transfer fluid channels 324 regulates the temperature of the lid 310.

A showerhead 318 may generally be coupled to an interior side 320 of the lid 310. A perforated blocker plate 336 may optionally be disposed in the space 322 between the showerhead 318 and lid 310. Gases (i.e., process and other gases) that enter the processing chamber 300 are first diffused by the blocker plate 336 as the gases fill the space 322 behind the showerhead 318. The gases then pass through the showerhead 318 and into the processing chamber 300. The blocker plate 336 and the showerhead 318 are configured to provide a uniform flow of gases to the processing chamber 300. Uniform gas flow advantageously promotes uniform layer formation on the substrate 303.

A gas source 360 is coupled to the lid 310 to provide gas through gas passages in the showerhead 318 to a processing area between the showerhead 318 and the substrate 303. A vacuum pump (not shown) may be coupled to the processing chamber 300 to control the processing volume at a predetermined pressure. An RF source 370 is coupled through a match network 390 to the lid 310 and/or to the showerhead 318 to provide an RF current to the showerhead 318. The RF current creates an electric field between the showerhead 318 and the substrate support assembly 338 so that plasma may be generated from the gases between the showerhead 318 and the substrate support assembly 338.

A remote plasma source 380, such as an inductively coupled remote plasma source, may also be coupled between the gas source 360 and the lid 310. Between processing substrates, a cleaning gas may be provided to the remote plasma source 380 so that remote plasma is generated. The radicals from the remote plasma may be provided to the processing chamber for a plasma etching process. The etching gas may be further excited by the RF source 370 provided to the showerhead 318.

The process chamber 300 includes a controller 340. The controller 340 comprises a central processing unit (CPU) 354, a memory 352, and support circuits 356 for the CPU 354 and facilitates control of the components of the process chamber 300 and, as such, of the method 100, as discussed herein in further detail. To facilitate control of the process chamber 300 as described above, the controller 340 may be any form of general-purpose computer processor that can be used in an industrial setting for controlling various chambers and sub-processors. The memory 352, or computer-readable medium, of the CPU 354 may be one or more of readily available memory such as random access memory (RAM), read only memory (ROM), floppy disk, hard disk, or any other form of digital storage, local or remote. The support circuits 356 are coupled to the CPU 354 for supporting the processor in a conventional manner. These circuits include cache, power supplies, clock circuits, input/output circuitry and subsystems, and the like. The inventive method described herein is generally stored in the memory 352 as a software routine. The software routine may also be stored and/or executed by a second CPU (not shown) that is remotely located from the hardware being controlled by the CPU 354.

While the foregoing is directed to embodiments of the present disclosure, other and further embodiments of the disclosure may be devised without departing from the basic scope thereof.

1. A method of controlling an etch profile, comprising:
introducing a tungsten containing gas into a processing chamber;
depositing a first tungsten film lining sidewalls of a feature formed in a substrate using the tungsten containing gas in the processing chamber; and
treating the first tungsten film in the processing chamber using the tungsten containing gas until a particular etch profile is attained by repeatedly alternating between etching the first tungsten film for a first interval and stopping the etching of the first tungsten film for a second interval by at least one of purging the tungsten containing gas from the process chamber or turning off a power supply that powers the etching of the first tungsten film.

2. The method of claim 1, further comprising:
introducing an inert gas into the process chamber prior to purging the tungsten containing gas from the processing chamber.

3. The method of claim 2, wherein the inert gas is at least one of helium or argon.

4. The method of claim 1, wherein etching the first tungsten film includes a plasma process and turning off the power supply that powers the etching of the first tungsten film includes removing RF power.

5. The method of claim 1, wherein etching the first tungsten film includes a plasma process carried out at a substrate temperature of about 100° C. to about 600° C.

6. The method of claim 1, wherein etching the first tungsten film includes a plasma process carried out at a chamber pressure of about 0.1 Torr to about 5 Torr.

7. The method of claim 1, wherein etching the first tungsten film includes a plasma process carried out at a flow rate of about 100 sccm to about 3,000 sccm.

8. The method of claim 1, wherein etching the first tungsten film includes a plasma process carried out at an RF power of about 50 W to about 100 W.

9. The method of claim 1, wherein etching the first tungsten film includes a plasma process carried out an RF power frequency from about 10 MHz to about 30 MHZ.

10. The method of claim 1, wherein etching the first tungsten film includes a plasma process in which a plasma is formed in a remote plasma source.

11. The method of claim 10, wherein the plasma is formed in the remote plasma source at a flow rate of about 500 sccm to about 6,000 sccm.

12. The method of claim 10, wherein the plasma is formed in the remote plasma source at an RF power of about 1000 W to about 6000 W.

13. The method of claim 1, wherein the first interval is about 1 sec to about 5 sec, and the second interval is about 1 sec to about 10 sec.

14. The method of claim 1, wherein depositing the first tungsten film includes forming the first tungsten film atop the adhesion layer in the processing chamber, and further comprising forming an adhesion layer along the sidewalls of the feature in the processing chamber.

15. The method of claim 1, wherein sidewalls of the feature slant towards each other at an upper part of the feature.

16. The method of claim 1, further comprising:
forming a second tungsten film atop the first tungsten film after treating the first tungsten film.

17. A method of controlling an etch profile, comprising:
forming an adhesion layer along sidewalls of a feature formed in a substrate, wherein sidewalls of the feature slant towards each other at an upper part of the feature;
introducing a tungsten containing gas into a processing chamber having the substrate disposed therein;
forming, using the tungsten containing gas, a first tungsten film atop the adhesion layer in the processing chamber;
treating the first tungsten film in the processing chamber using the tungsten containing gas until a particular etch profile is attained by repeatedly alternating between plasma etching the first tungsten film for a first interval of about 1 sec to about 5 sec and stopping the etching of the first tungsten film for a second interval of about 1 sec to about 10 sec by at least one of purging the tungsten containing gas from the process chamber or turning off RF power that generates the plasma; and
forming a second tungsten film atop the first tungsten film after treating the first tungsten film.

18. A non-transitory computer readable medium having instructions stored thereon that, when executed, cause a method of controlling an etch profile, comprising:
introducing a tungsten containing gas into a processing chamber;
depositing a first tungsten film lining sidewalls of a feature formed in a substrate using the tungsten containing gas in the processing chamber; and
treating the first tungsten film in the processing chamber using the tungsten containing gas until a particular etch profile is attained by repeatedly alternating between etching the first tungsten film for a first interval and stopping the etching of the first tungsten film for a second interval by at least one of purging the tungsten containing gas from the process chamber or turning off a power supply that powers the etching of the first tungsten film.

19. The non-transitory computer readable medium of claim 18, wherein the first interval is about 1 sec to about 5 sec, and the second interval is about 1 sec to about 10 sec.

20. The non-transitory computer readable medium of claim 18, further comprising:
forming an adhesion layer along the sidewalls of the feature in the processing chamber; and
wherein depositing the first tungsten film includes forming the first tungsten film atop the adhesion layer in the processing chamber.
